(19) United States
(12) Patent Application Publication
(10) Pub. No.: US 2024/0053382 A1
(43) Pub. Date: Feb. 15, 2024

(54) PROBE PIN AND METHOD OF MANUFACTURING PROBE PIN

(71) Applicant: PT&K CO., LTD., Anyang-si (KR)

(72) Inventors: Tae Yoon KIM, Gunpo-si (KR); Sung Chul KIM, Gunpo-si (KR)

(21) Appl. No.: 18/495,795

(22) Filed: Oct. 27, 2023

Related U.S. Application Data
(63) Continuation of application No. PCT/KR2022/005919, filed on Apr. 26, 2022.

(30) Foreign Application Priority Data
Apr. 30, 2021 (KR) 10-2021-0056805

(51) Int. Cl. G01R 1/067; G01R 3/00

(52) U.S. Cl. CPC G01R 1/06738; G01R 3/00; G01R 1/0675

(57) ABSTRACT

A probe pin includes a body portion; and a top portion and a tip portion connected to respective ends of the body portion. The body portion includes a first side surface and a third side surface facing each other and a second surface and a fourth side surface intersecting the first side surface and the third side surface, respectively, and facing each other, and has a bending portion at least in part. Each of the top portion and the tip portion has a circular cross-section, and the top portion, the body portion and the tip portion are formed as one body.

### TECHNICAL FIELD

The present disclosure relates to a probe pin and a method of manufacturing the probe pin.

### BACKGROUND

A semiconductor manufacturing process is composed of a pre-process of fabricating a plurality of semiconductor dies on a wafer and a post-process of fabricating a semiconductor package by connecting a line to each of the semiconductor dies.

In general, an electrical die sorting (EDS) process is performed to inspect electrical characteristics of each semiconductor die constituting the wafer. Specifically, the EDS process is performed by bringing a probe pin provided in a probe card into a contact pad of a semiconductor die, allowing an electrical signal from a separate semiconductor inspection device to pass through the probe pin, and reading an output electrical signal. This is referred to as “probe testing”.

Recently, with the advancement in semiconductor miniaturization, finer pitches have been required at a wafer level as well as semiconductor package level. Since pads on a semiconductor package have been miniaturized, a probe tip portion of a socket for inspecting the semiconductor package (semiconductor chip) needs to be reduced in size.

In general, the probe pin to be in contact with the pads on the semiconductor package for inspection of the semiconductor package is manufactured through a micro electro mechanical system (MEMS) process. The MEMS process is used in manufacturing semiconductors, and the probe pin is manufactured through, for example, a photolithography process.

However, the probe pin manufactured through the MEMS process is degraded in physical performance, or it is difficult to manufacture the probe tip portion into various shapes.

### SUMMARY

### Problems to be Solved by the Invention

The present disclosure is to solve the above-described problem, and provides a probe pin which has excellent physical characteristics by varying the material and shape of a tip portion.

### Means for Solving the Problems

According to an aspect of the present disclosure, a probe pin includes a body portion; and a top portion and a tip portion connected to respective ends of the body portion. The body portion includes a first side surface and a third side surface facing each other and a second surface and a fourth side surface intersecting the first side surface and the third side surface, respectively, and facing each other, and has a bending portion at least in part. Each of the top portion and the tip portion has a circular cross-section, and the top portion, the body portion and the tip portion are formed as one body.

According to an embodiment of the present disclosure, the first to fourth side surfaces are flat surfaces.

According to an embodiment of the present disclosure, the body portion has a rectangular cross-section with rounded corners.

According to an embodiment of the present disclosure, the top portion has a hemispherical shape, and the tip portion has a cone shape.

According to an embodiment of the present disclosure, a tip end of the tip portion is located at the center of the tip portion without being biased to one side.

According to an embodiment of the present disclosure, the bending portion is covered with an insulating coating surrounding an outer circumference of the bending portion.

According to another aspect of the present disclosure, a method of manufacturing a probe pin includes drawing a material; polishing one end of the drawn material into a horn shape and polishing the other end round; open-die forging the polished material to form a flat surface with respect to a side surface extending in a longitudinal direction; and die forging the open-die forged material to partially form a bending portion.

According to another embodiment of the present disclosure, in the open-die forging, the polished material is processed to have a first side surface and a third side surface by using a pressing device, and the material having the first side surface and third side surface is rotated 90 degrees to form a second side surface and a fourth side surface.

According to another embodiment of the present disclosure, in the open-die forging, the polished material is processed to simultaneously have first to fourth side surfaces by using a pressing device.

According to another embodiment of the present disclosure, the method of manufacturing a probe pin further includes insulating and coating a bending portion in the die forged material.

### Effects of the Invention

According to any one of the above-described means for solving the problems of the present disclosure, it is possible to provide a probe pin which has excellent physical characteristics by varying the material and shape of a tip portion.

### BRIEF DESCRIPTION OF THE DRAWINGS

FIG. 1A is a side view of a probe pin according to an embodiment of the present disclosure.

FIG. 1B is a cross-sectional view taken along a line A-A′ of FIG. 1A.

FIG. 1C is a cross-sectional view taken along a line B-B′ of FIG. 1A.

FIG. 1D is a cross-sectional view taken along a line C-C′ of FIG. 1A.

FIG. 2A is a cross-sectional view of the probe pin according to an embodiment of the present disclosure.

FIG. 2B is a conceptual diagram of a mounting plate having mounting holes into which the probe pin illustrated in FIG. 2A can be inserted.

FIG. 3A illustrates a top portion of the probe pin according to an embodiment of the present disclosure.

FIG. 3B illustrates a top portion of a probe pin manufactured through a MEMS process.

FIG. 4A illustrates a tip portion of the probe pin according to an embodiment of the present disclosure.

FIG. 4B illustrates a tip portion of the probe pin manufactured through the MEMS process.

FIG. 5 is a flowchart showing a method of manufacturing a probe pin according to an embodiment of the present disclosure.

FIG. 6 is a perspective view schematically illustrating shape changes of a material in a process of manufacturing a probe pin according to an embodiment of the present disclosure.

FIG. 7A is a conceptual diagram of a pressing device to be used in an open-die forging process according to an embodiment of the present disclosure.

FIG. 7B is a conceptual diagram of a pressing device to be used in an open-die forging process according to another embodiment of the present disclosure.

### BEST MODE FOR CARRYING OUT THE INVENTION

Hereinafter, embodiments of the present disclosure will be described in detail with reference to the accompanying drawings so that the present disclosure may be readily implemented by a person with ordinary skill in the art. However, it is to be noted that the present disclosure is not limited to the embodiments but can be embodied in various other ways. In drawings, parts irrelevant to the description are omitted for the simplicity of explanation, and like reference numerals denote like parts through the whole document.

In the present disclosure, the terms of a singular form may include plural forms unless otherwise specified.

In the following description of the present disclosure, a detailed explanation of known related technologies may be omitted to avoid unnecessarily obscuring the subject matter of the present disclosure.

In the present disclosure, the terms indicating positions or directions such as “upper”, “lower”, “left”, “right”, “front” and “rear” have been used only for describing relative positions or directions of objects based on the drawings, but do not limit the present disclosure.

The accompanying drawings are provided only for a better understanding of the embodiments disclosed in the present disclosure and are not intended to limit technical ideas disclosed in the present disclosure. Therefore, it should be understood that the accompanying drawings include all modifications, equivalents and substitutions within the scope and sprit of the present disclosure.

Hereinafter, an embodiment of the present disclosure will be described in detail with reference to the accompanying drawings.

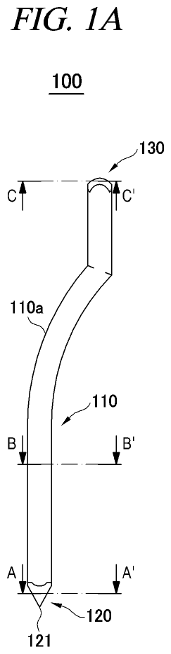

FIG. 1 illustrates a probe pin to be mounted in a probe card according to an embodiment of the present disclosure. FIG. 1A is a side view of a probe pin 100, FIG. 1B is a cross-sectional view taken along a line A-A′ of FIG. 1A, FIG. 1C is a cross-sectional view taken along a line B-B′ of FIG. 1A, and FIG. 1D is a cross-sectional view taken along a line C-C′ of FIG. 1A.

As shown in the drawings, the probe pin 100 may include a body portion 110, and a top portion 130 and a tip portion 120 formed at respective ends of the body portion 110. The probe pin 100 is formed of an alloy, and the body portion 110, the top portion 130 and the tip portion 120 may be formed as one body.

In the probe pin 100, the tip portion 120 may be in contact with a contact pad of a semiconductor chip to be inspected and the top portion 130 may be connected to an inspection device in order to electrically connect the contact pad of the semiconductor chip and the inspection device.

When the tip portion 120 of the probe pin 100 is in contact with the contact pad of the semiconductor chip, a load is applied to the probe pin 100 in a contact direction. Therefore, in general, at least a part, desirably an intermediate portion, of the body portion 110 extending in a vertical direction may be provided with a bending portion 110a.

The bending portion 110a may be covered with an insulating coating formed of polymide, acryl, parylene, or a combination thereof. The insulating coating may be provided to surround an outer circumference of the bending portion 110a.

The body portion 110 may include a first side surface 111, a second side surface 112, a third side surface 113, and a fourth side surface 114. The first side surface 111 and the third side surface 113 may face each other, and the second side surface 112 and the fourth side surface 114 may face each other. Further, the first side surface 111 and the third side surface 113 may intersect the second side surface 112 and the fourth side surface 114, respectively. Furthermore, the respective side surfaces may be flat surfaces or substantially flat surfaces.

The body portion 110 may have a substantially quadrangular cross-section, desirably a rectangular cross-section. In particular, the body portion 110 may have a rectangular shape having the second and fourth side surfaces 112 and 114 and the first and third side surfaces 111 and 113 which are different in length from the second and fourth side surfaces 112 and 114.

When a load is applied to the probe pin 100 including the body portion 110 having a rectangular cross-section, it is possible to predict which direction the probe pin 100 will be bent. Therefore, whenever the probe pin 100 is bent by a load consecutively applied thereto, it is possible to suppress interference which may occur between the adjacent probe pins 100.

In other words, a probe pin having a circular cross-section can be bent in any direction by a load consecutively applied thereto since it has the same thickness (diameter) in any direction, whereas the probe pin 100 having a rectangular cross-section is not bent toward a corner direction or a side with a greater thickness, but bent toward a side with a smaller thickness by load consecutively applied thereto.

Therefore, the probe pin 100 having a rectangular cross-section can be configured such that the probe pin 100 being bent in any direction does not interfere between the adjacent probe pins 100. Accordingly, it is possible to improve reliability in inspection of the semiconductor chip.

Also, the body portion 110 may have a substantially quadrangular cross-section, desirably a rectangular cross-section with rounded corners. That is, the first and third side surfaces 111 and 113 may intersect the second and fourth side surfaces 112 and 114, respectively, at an angle of about 90 degrees and meet the second and fourth side surfaces 112 and 114 at rounded corners, respectively. The rectangular cross-section with rounded corners can be matched with the shape of a mounting hole 251 of a mounting plate 250 used for connecting a probe pin to a substrate (a printed circuit board or a space transformer substrate) when a probe card for semiconductor wafer or a socket for semiconductor package is manufactured. That is, the mounting hole 251 is generally formed in the mounting plate 250 by using a laser, and when a hole is formed by irradiating a laser onto the mounting plate 250, the hole has a corner-rounded quadrangular shape. If a probe pin having a circular cross-section is inserted into the hole having the above-described shape, the cross-sectional shape of the probe pin is not matched with the hole of the mounting plate, which can cause instability in inspection. According to the present disclosure, the probe pin has the body portion having a corner-rounded quadrangular shape matched with the hole of the mounting plate, which can cause more stability in inspection.

Meanwhile, the tip portion 120 may be formed on one side of the body portion 110. The tip portion 120 may include a sharp tip end 121, and may have a horn shape and desirably a cone shape. The tip portion 120 may have a circular cross-section gradually decreasing in size until it ends. Since the tip portion 120 has a circular cross-section, a point contact can be achieved when the tip portion 120 is in contact with a contact pad on a semiconductor wafer or a semiconductor package. Therefore, it is possible to minimize the size of a scrub mark. According to the present disclosure, if the tip portion is formed through a MEMS process, it is possible to solve the problem of a relatively large-sized scrub mark caused by a quadrangular cross-section.

The tip end 121 of the tip portion 120 may be located at the center of the tip portion 120 without being biased to one side. The tip portion 120 may have a right circular cone shape. According to the present disclosure, if the tip portion is formed through the MEMS process, it is possible to solve the problem of biased formation of the tip end of the tip portion. The tip end of the tip portion can be formed at the center of the tip portion through the MEMS process. However, in this case, a photolithography process is performed several times, which causes an increase in manufacturing cost.

The top portion 130 may be formed on the other side of the body portion 110 and may be gently rounded without any angled portion. The top portion 130 may have a rounded end, particularly a hemispherical shape. The top portion 130 may have a circular cross-section.

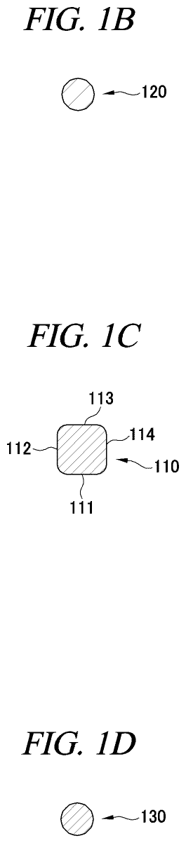

FIG. 2 compares a cross-section of a body portion 210 of the probe pin according to an embodiment of the present disclosure with a shape of the mounting hole 251 into which the probe pin is inserted. FIG. 2A is a cross-sectional view of the body portion 210 of the probe pin according to an embodiment of the present disclosure, and FIG. 2B is a conceptual diagram of the mounting plate 250 having the mounting holes 251 into which the probe pin can be inserted.

As illustrated in FIG. 2A, the body portion 210 of the probe pin according to an embodiment of the present disclosure has a rectangular cross-section with rounded corners.

The probe pin is a component of the probe card and is mounted on the mounting plate 250, which is another component of the probe card. Specifically, as illustrated in FIG. 2B, a number of mounting hole 251 are formed in the mounting plate 250, and the probe pin may be mounted on the mounting plate 250 in a state where a part of the probe pin is inserted in the mounting hole 251.

The mounting hole 251 in the mounting plate 250 is formed by irradiating a laser onto the mounting plate 250. Herein, the mounting hole 251 is formed into a rectangular shape with rounded corners.

Therefore, the body portion 210 has a rectangular cross-section with rounded corners and thus corresponds in shape to mounting hole 251 formed in the mounting plate 250 by using a laser. Accordingly, when the probe pin is mounted on the mounting plate 250, a part of the probe pin can be stably inserted and fixed in the mounting hole 251.

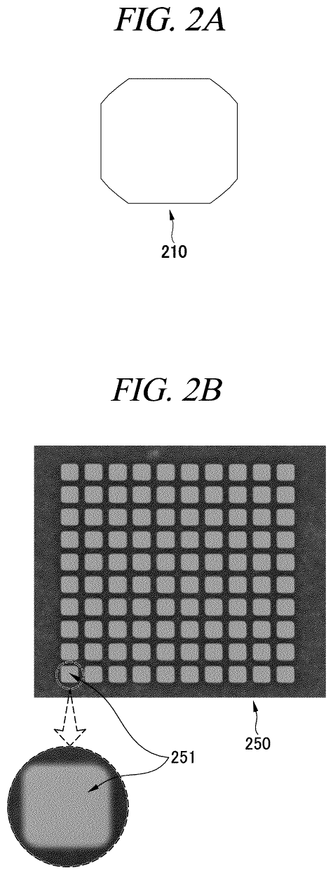

FIG. 3 compares a top portion 330 of the probe pin according to an embodiment of the present disclosure with a top portion 360 of a probe pin manufactured through the MEMS process. FIG. 3A illustrates the top portion 330 of the probe pin according to an embodiment of the present disclosure, and FIG. 3B illustrates the top portion 360 of the probe pin manufactured through the MEMS process.

Since the MEMS process uses a photolithography process, it is difficult to form an end of the top portion 360 to be rounded without any angled portion.

As illustrated in the drawings, the top portion 330 of the probe pin according to an embodiment of the present disclosure has a rounded end, whereas the top portion 360 of the probe pin manufactured through the MEMS process has an angled portion.

A top portion of a probe pin is to be in contact with a conductor formed on an inspection device. When a load is consecutively applied to the probe pin, the relative position of the top portion of the probe pin to be in contact with the conductor formed on the inspection device continuously changes.

In other words, when a load is applied to the probe pin, the probe pin is bent. Therefore, the position of the top portion of the probe pin to be in contact with the conductor formed on the inspection device before the load is applied may be different from the position of the top portion of the probe pin to be in contact with the conductor formed on the inspection device while the load is applied.

In this case, if the top portion 330 of the probe pin has a rounded end as illustrated in FIG. 3A, a contact area between the conductor and the top portion 330 may remain constant even when the relative position of the top portion 330 of the probe pin to be in contact with the conductor formed on the inspection device changes.

Meanwhile, if the top portion 360 of the probe pin has an angled portion and is not uniform in shape at a specific position as illustrated in FIG. 3B, the relative position of the top portion 360 of the probe pin to be in contact with the conductor formed on the inspection device whenever a load is applied to the probe pin changes, and, thus, a contact area between the conductor and the top portion 360 also changes. This may hinder a stable contact between the conductor formed on the inspection device and the top portion of the probe pin.

Therefore, the probe pin according to an embodiment of the present disclosure is favorable for keeping a stable contact between the top portion of the probe pin and the conductor (port) formed on the inspection device, as compared with the probe pin manufactured through the MEMS process.

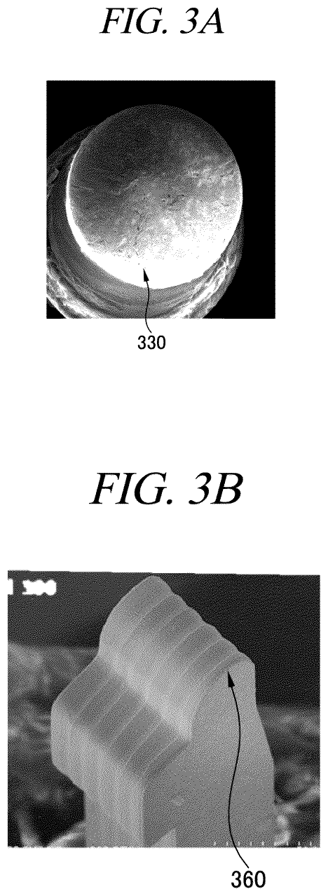

FIG. 4 compares a tip portion 420 of the probe pin according to an embodiment of the present disclosure with a tip portion 460 of the probe pin manufactured through the MEMS process. FIG. 4A illustrates the tip portion 420 of the probe pin according to an embodiment of the present disclosure, and FIG. 4B illustrates the tip portion 460 of the probe pin manufactured through the MEMS process.

A tip portion of a probe pin is to be in contact with a contact pad of a semiconductor chip. As illustrated in FIG. 4A, the tip portion 420 of the probe pin according to an embodiment of the present disclosure may have a sharp end, and a tip end 421 may be located at the center of the tip portion 420 without being biased to one side.

When the tip portion 420 comes in contact with the contact pad, the sharp tip end 421 enables the tip portion 420 to penetrate an oxide film formed on the contact pad and come in contact with the contact pad without any error.

Also, since the tip end 421 of the tip portion 420 is located at the center of the tip portion 420, the tip end 421 does not deviate from an area of the contact pad and enables a contact at a central portion of the contact pad when the tip portion 420 comes in contact with the contact pad. Thus, the tip end 421 facilitates a stable contact.

However, as for the probe pin manufactured through the MEMS process as illustrated in FIG. 4B, it is not easy to form a tip portion whose end is sharp and tip end is located at the center due to the characteristics of the MEMS process.

Therefore, the probe pin according to an embodiment of the present disclosure is favorable for keeping a stable contact between the probe pin and the contact pad, as compared with the probe pin manufactured through the MEMS process.

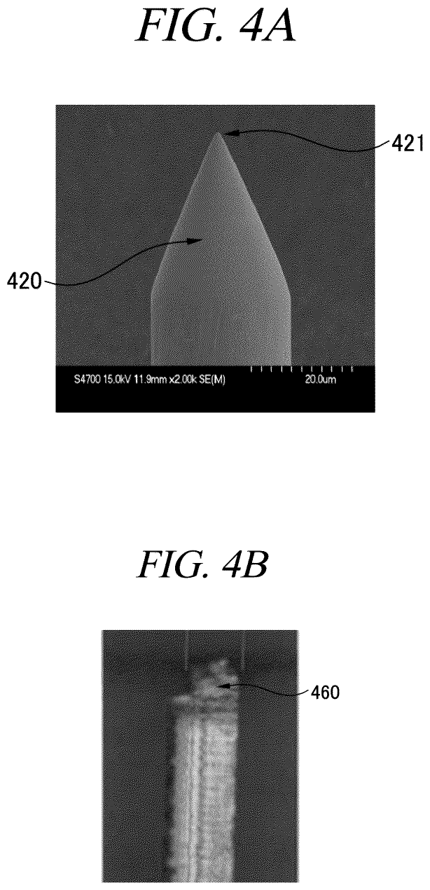

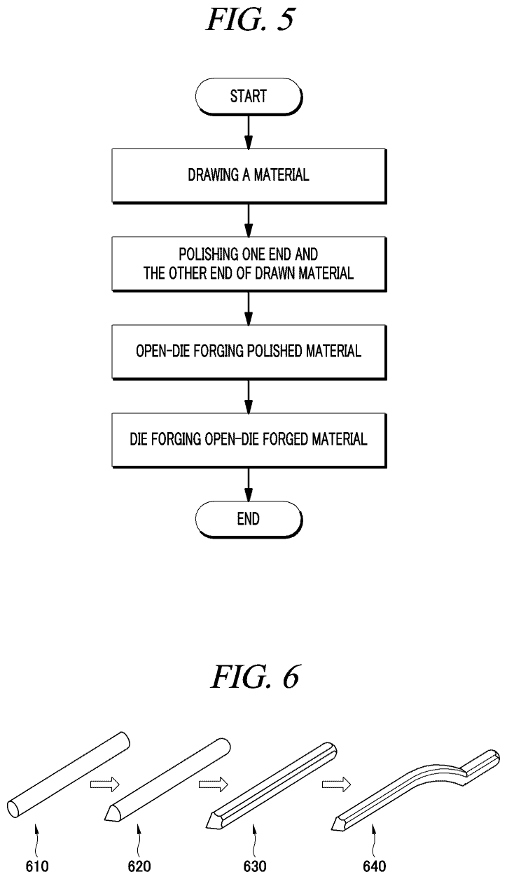

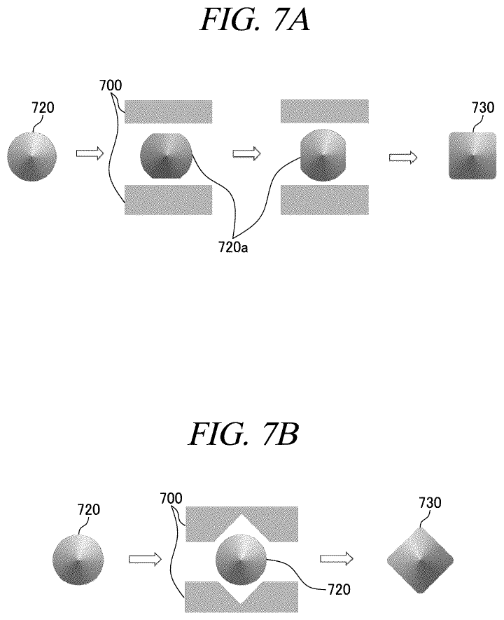

FIG. 5 is a flowchart showing a method of manufacturing a probe pin according to an embodiment of the present disclosure, FIG. 6 is a perspective view schematically illustrating shape changes of a material in a process of manufacturing a probe pin according to an embodiment of the present disclosure, and FIG. 7 is a conceptual diagram of a pressing device to be used in an open-die forging process according to an embodiment of the present disclosure. FIG. 7A illustrates a pressing device that performs an open-die forging process through two stages, and FIG. 7B illustrates a pressing device that performs an open-die forging process through one stage.

As illustrated in FIG. 5, the method of manufacturing a probe pin may include a process of drawing a material, a process of polishing one end and the other end of the drawn material, a process of open-die forging the polished material, and a process of die forging the open-die forged material.

Referring to FIG. 6, a drawn material 610 may have a cylindrical shape having a circular cross-section and extending in a longitudinal direction.

A material of the probe pin may be selected from alloys having excellent conductivity as necessary. Therefore, the drawn material 610 does not require a separate plating process and does not have layers unlike a probe pin, which is manufactured through the MEMS process and in which deposition materials are layered, and thus can provide stable physical characteristics.

In the drawn material which has a cylindrical shape, one end may be polished into a horn shape, desirably a cone shape.

For example, the drawn material may be polished by a machining device. The drawn material which has a cylindrical shape may be polished by a whetstone while being rotated around a central axis a. The whetstone may polish one end of the drawn material into a cone shape.

Specifically, it is relatively easy to process an end portion of the drawn material by rotation of the drawn material and a two-dimensional behavior of the whetstone. If the whetstone moves to the end of the drawn material so as to be gradually closer to a rotation axis while the drawn material is rotated, one end of the drawn material can be polished into a cone shape. In particular, the drawn material may be polished into a right circular cone shape whose tip end is located at the center.

The other end of the drawn material may be polished round simultaneously with, or before, or after the process of polishing one end of the drawn material.

A polished material 620 may be open-die forged to flatten a round surface with respect to a side surface extending in the longitudinal direction.

The polished material may be open-die forged by using a pressing device having a pair of hammers 700 facing each other as illustrated in FIG. 7.

In an embodiment, the hammers 700 may press a polished material 720 in a state where the polished material 720 is placed between the pair of hammers 700 to form a material 720a open-die forged in one direction as illustrated in FIG. 7A. The material 720a open-die forged in one direction may have a pair of flat surfaces facing each other, i.e., a first side surface and a third side surface.

Thereafter, the material 720a may be rotated 90 degrees and then pressed again to form a second side surface and a fourth side surface which intersect the first side surface and the third side surface, respectively, and face each other.

When the polished material is open-die forged, a pressure to be applied to the material by the pressing device may be adjusted in order for corners of a cross-section of the open-die forged portion not to be angled.

An open-die forged material 730 may have a rectangular shape, desirably a rectangular shape with rounded corners, when viewed from the front, and may have a tip end at the center.

In another embodiment, the first to fourth side surfaces of the polished material 720 may be open-die forged simultaneously as illustrated in FIG. 7B. In this case, the pressing device has the pair of hammers 700 facing each other, and respective facing side surfaces of the hammers 700 may include substantially “V”-shaped notches corresponding to each other. In a state where the pair of hammers 700 are disposed adjacent to each other, the notches formed in the respective hammers may form a quadrangular shape.

Although not illustrated in the drawings, the pressing device may be provided with a pair of hammers facing each other and another pair of hammers interesting the pair of hammers and facing each other to simultaneously open die forge the four side surfaces of the polished material.

The polished material may be placed between the pair of hammers and pressed by the pair of hammers. Thus, the material may simultaneously have the first and third side surfaces and the second and fourth side surfaces with respect to the side surface extending in the longitudinal direction.

Likewise, when the four side surfaces of the polished material are simultaneously open-die forged, corners of a cross-section of the open-die forged portion may not to be angled.

Referring back to FIG. 6, an open-die forged material 630 may be die forged to partially form a bending portion.

Also, according to an embodiment of the present disclosure, the method may further include a process of insulating and coating the bending portion in a die forged material 640.

The above description of the present disclosure is provided for the purpose of illustration, and it would be understood by a person with ordinary skill in the art that various changes and modifications may be made without changing technical conception and essential features of the present disclosure. Thus, it is clear that the above-described examples are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure.

We claim:

1. A probe pin, comprising:
a body portion; and
a top portion and a tip portion connected to respective ends of the body portion,
wherein the body portion includes a first side surface and a third side surface facing each other and a second surface and a fourth side surface intersecting the first side surface and the third side surface, respectively, and facing each other, and has a bending portion at least in part,
each of the top portion and the tip portion has a circular cross-section, and
the top portion, the body portion and the tip portion are formed as one body.

2. The probe pin of claim 1,
wherein the first to fourth side surfaces are flat surfaces.

3. The probe pin of claim 1,
wherein the body portion has a rectangular cross-section with rounded corners.

4. The probe pin of claim 3,
wherein the top portion has a hemispherical shape, and
the tip portion has a cone shape.

5. The probe pin of claim 1,
wherein a tip end of the tip portion is located at the center of the tip portion without being biased to one side.

6. The probe pin of claim 1,
wherein the bending portion is covered with an insulating coating surrounding an outer circumference of the bending portion.

7. A method of manufacturing a probe pin, comprising:
drawing a material;
polishing one end of the drawn material into a horn shape and polishing the other end round;
open-die forging the polished material to form a flat surface with respect to a side surface extending in a longitudinal direction; and
die forging the open-die forged material to partially form a bending portion.

8. The method of manufacturing a probe pin of claim 7,
wherein in the open-die forging,
the polished material is processed to have a first side surface and a third side surface by using a pressing device, and
the material having the first side surface and third side surface is rotated 90 degrees to form a second side surface and a fourth side surface.

9. The method of manufacturing a probe pin of claim 7,
wherein in the open-die forging,
the polished material is processed to simultaneously have first to fourth side surfaces by using a pressing device.

10. The method of manufacturing a probe pin of claim 7, further comprising:
insulating and coating a bending portion in the die forged material.
